(19) United States
(12) Patent Application Publication
(10) Pub. No.: US 2016/0251755 A1
(43) Pub. Date: Sep. 1, 2016

(54) METHOD AND APPARATUS FOR FORMING CARBON FILM

(71) Applicant: TOKYO ELECTRON LIMITED, Tokyo (JP)

(72) Inventors: Masayuki KITAMURA, Nirasaki City (JP); Satoshi MIZUNAGA, Oshu-shi (JP); Akira SHIMIZU, Nirasaki City (JP); Akinobu KAKIMOTO, Nirasaki City (JP)

(21) Appl. No.: 15/045,792

(22) Filed: Feb. 17, 2016

(30) Foreign Application Priority Data
Feb. 26, 2015 (JP) 2015-036406

(51) Int. Cl. C23C 16/02; C23C 16/26

(52) U.S. Cl. CPC C23C 16/0272; C23C 16/26

(57) ABSTRACT

A method for forming a carbon film on a process surface to be processed of a workpiece includes forming a seed layer on the process surface of the workpiece by supplying an aminosilane-based gas, an aminosilane-based gas having high-order equal to or higher than that of aminodisilane, or a nitrogen-containing heterocyclic compound gas onto the process surface; and forming the carbon film on the process surface on which the seed layer is formed by supplying a hydrocarbon-based carbon source gas and a thermal decomposition temperature lowering gas for lowering a thermal decomposition temperature of the hydrocarbon-based carbon source gas onto the process surface on which the seed layer is obtained, and by setting a film formation temperature to be lower than the thermal decomposition temperature of the hydrocarbon-based carbon source gas.

### CROSS-REFERENCE TO RELATED APPLICATION

This application claims the benefit of Japanese Patent Application No. 2015-036406, filed on Feb. 26, 2015, in the Japan Patent Office, the disclosure of which is incorporated herein in its entirety by reference.

### TECHNICAL FIELD

The present disclosure relates to a method and apparatus for forming a carbon film.

### BACKGROUND

Carbon (C) is attracting attention as one of the next generation semiconductor materials. An example of a method for forming a carbon film may include a plasma CVD method and a thermal CVD method which are known in the art.

However, the formation of carbon film using the plasma CVD method may provide poor step coverage although it may limit a film formation temperature to a low temperature (for example, 150 to 350 degrees C.). For this reason, the formation of carbon film using the plasma CVD method is not suitable for an underlying layer having unevenness such as a line pattern, a hole pattern or the like.

In addition, the formation of carbon film using the thermal CVD method needs to provide a high film formation temperature (for example, 800 to 1000 degrees C.) although it may achieve better step coverage than the plasma CVD method. For this reason, the formation of carbon film using the thermal CVD method is not suitable for a process for an upper layer of a semiconductor device, for example from the viewpoint of a heat history to transistors formed on a silicon wafer.

To avoid these problems, one proposal is to form a carbon film at a temperature lower than that in the conventional thermal CVD method by supplying a hydrocarbon-based carbon source gas and a thermal decomposition temperature lowering gas for lowering a thermal decomposition temperature of the carbon source gas when a carbon film is formed.

In this proposed technique for forming the carbon film while supplying the hydrocarbon-based carbon source gas and the thermal decomposition temperature lowering gas for lowering the thermal decomposition temperature of the carbon source gas, it is possible to form the carbon film at a film formation temperature which is lower than that in the conventional thermal CVD method, for example, equal to or lower than 650 degrees C.

However, such decrease of the film formation temperature to 650 degrees C. or lower may result in increase in incubation time when the carbon film is formed.

### SUMMARY

Some embodiments of the present disclosure provide a method for forming a carbon film, which is capable of shortening an incubation time even when a thermal decomposition temperature lowering gas is used to form the carbon film and a film formation temperature is set to be lower than a thermal decomposition temperature of a hydrocarbon-based carbon source gas, and a film forming apparatus capable of performing the same method.

According to the present disclosure, there is provided a method for forming a carbon film on a process surface to be processed of a workpiece, the method including: forming a seed layer on the process surface of the workpiece by supplying an aminosilane-based gas, an aminosilane-based gas having high-order equal to or higher than that of aminodisilane, or a nitrogen-containing heterocyclic compound gas onto the process surface; and forming the carbon film on the process surface on which the seed layer is formed by supplying a hydrocarbon-based carbon source gas and a thermal decomposition temperature lowering gas for lowering a thermal decomposition temperature of the hydrocarbon-based carbon source gas onto the process surface on which the seed layer is obtained, and by setting a film formation temperature to be lower than the thermal decomposition temperature of the hydrocarbon-based carbon source gas.

According to the present disclosure, there is provided an film forming apparatus for forming a carbon film on a process surface to be processed of a workpiece, including: a processing chamber in which the workpiece having the process surface on which the carbon film is to be formed is accommodated; a processing gas supply mechanism configured to supply a gas to be used for processing into the processing chamber a heater configured to heat the workpiece accommodated in the processing chamber; and a controller configured to control the processing gas supply mechanism and the heater so as to perform the carbon film forming method described above.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a flowchart showing one example of a sequence of a method for forming a carbon film according to a first embodiment of the present disclosure.

FIGS. 2A to 2C are schematic sectional views showing a state of a work piece in the sequence shown in FIG. 1.

FIG. 3A is a view showing a triazole-based compound.

FIG. 3B is a view showing an oxatriazole-based compound.

FIG. 3C is a view showing a tetrazole-based compound.

FIG. 3D is a view showing a triazine-based compound.

FIG. 3E is a view showing a tetrazine-based compound (1,2,3,4-tetrazine-based compound.

FIG. 3F is a view showing a tetrazine-based compound (1,2,3,5-tetrazine-based compound.

FIG. 3G is a view showing a benzotriazole-based compound.

FIG. 3H is a view showing a benzotriazine-based compound.

FIG. 3I is a view showing a benzotetrazine-based compound.

FIG. 4 is a view showing the relationship between film formation time and carbon film thickness.

FIG. 5 is a schematic sectional view showing one example of a vertical batch type film forming apparatus according to a second embodiment of the present disclosure.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments. Hereinafter, embodiments of the present disclosure will be described with reference to the drawings. Throughout the drawings, the same elements and portions are denoted by the same reference numerals.

### First Embodiment

### <Method for Forming Carbon Film>

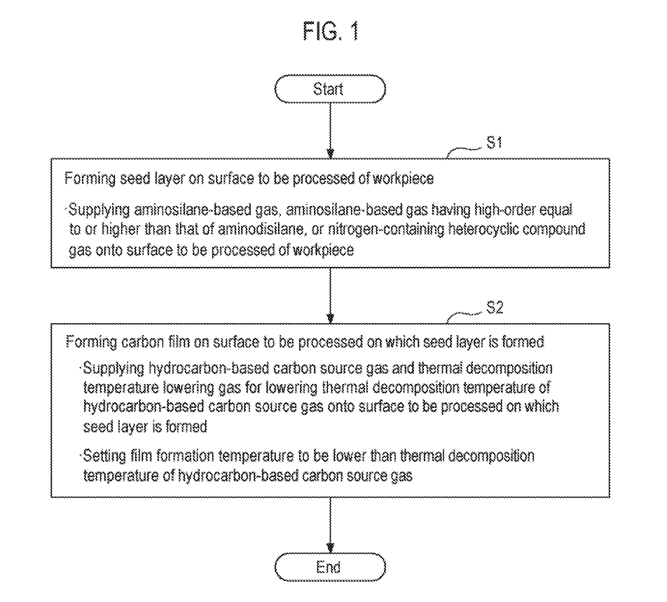

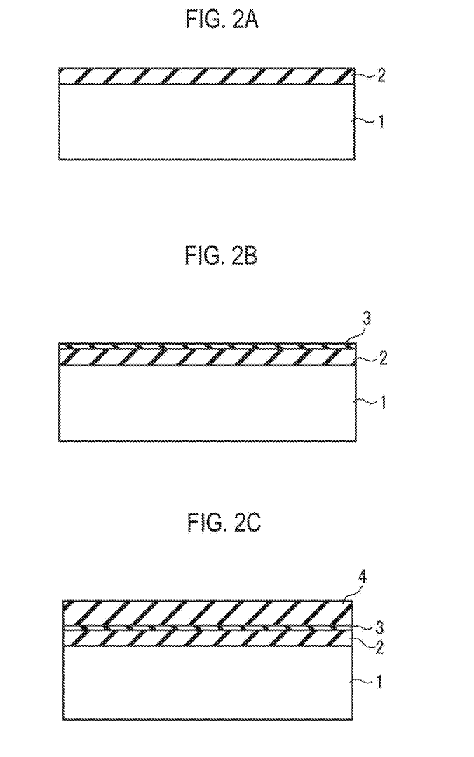

FIG. 1 is a flowchart showing one example of a sequence of a method for forming a carbon film according to a first embodiment of the present disclosure. FIGS. 2A to 2C are schematic sectional views showing a state of a work piece in the sequence shown in FIG. 1.

First, as shown in FIG. 2A, a silicon wafer (hereinafter referred simply to as a wafer) 1 having a front surface on which a silicon oxide film 2 is formed is prepared as a workpiece. One example of the silicon oxide film 2 is an SiO₂ film.

Next, as shown in Step S1 of FIG. 1 and in FIG. 2B, a seed layer 3 is formed on a surface to be processed of the workpiece (in this embodiment, an exposed surface of the silicon oxide film 2) by supplying an aminosilane-based gas, an aminosilane-based gas having high-order equal to or higher than that of aminodisilane, or a nitrogen-containing heterocyclic compound gas onto the surface to be processed (the surface of the silicon oxide film 2). A processing temperature in Step S1 is set to be higher than a thermal decomposition temperature of each of the aminosilane-based gas, the aminosilane-based gas having high-order equal to or higher than that of aminodisilane, and the nitrogen-containing heterocyclic compound gas.

An example of the aminosilane-based gas may include a gas containing at least one of:

BAS (butylaminosilane),

BTBAS (bistertiarybutylaminosilane),

DMAS (dimethylaminosilane),

BDMAS (bisdimethylaminosilane),

TDMAS (trisdimethylaminosilane),

DEAS (diethylaminosilane),

BDEAS (bisdiethylaminosilane),

DPAS (dipropylaminosilane), and

DIPAS (diisopropylaminosilane).

An example of the aminosilane-based gas having high-order equal to or higher than that of aminodisilane may include a gas containing at least one of amino compounds expressed by a molecular formula:

((R1R2)N)ₙSi_{X}H_{2X+2-n-m}(R3)ₘ (A), or

((R1R2)N)ₙSi_{X}H_{2X-n-m}(R3)ₘ (B).

In the formulas (A) and (B), n represents the number of amino groups equal to or higher than “1”, m represents the number of alkyl groups equal to “0” or equal to or higher than “1”, R1 and R2 are independently selected from a group consisting of CH₃, C₂H₅ and C₃H₇, R3 is selected from a group consisting of CH₃, C₂H₅, C₃H₇ and Cl, and X is a number of “2” or more (but, in practice, preferably “2” or “3”).

An example of the high-order aminosilane-based gas expressed by the formula (A) may include:

diisopropylaminodisilane (Si₂H₅N(iPr)₂),

diisopropylaminotrisilane (Si₃H₇N(iPr)₂),

diisopropylaminochlorodisilane (Si₂H₄ClN(iPr)₂), and

diisopropylaminochlorotrisilane (Si₃H₆ClN(iPr)₂).

An example of the high-order aminosilane-based gas expressed by the formula (B) may include:

diisopropylaminocyclotrisilane (Si₃H₅N(iPr)₂), and

diisopropylaminochlorocyclotrisilane (Si₃H₄ClN(iPr)₂).

An example of the nitrogen-containing heterocyclic compound gas may include a gas containing at least one of:

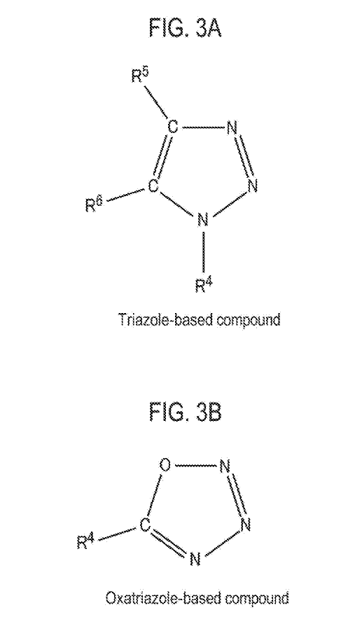

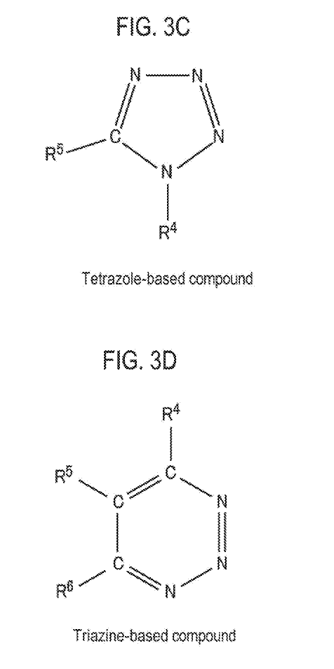

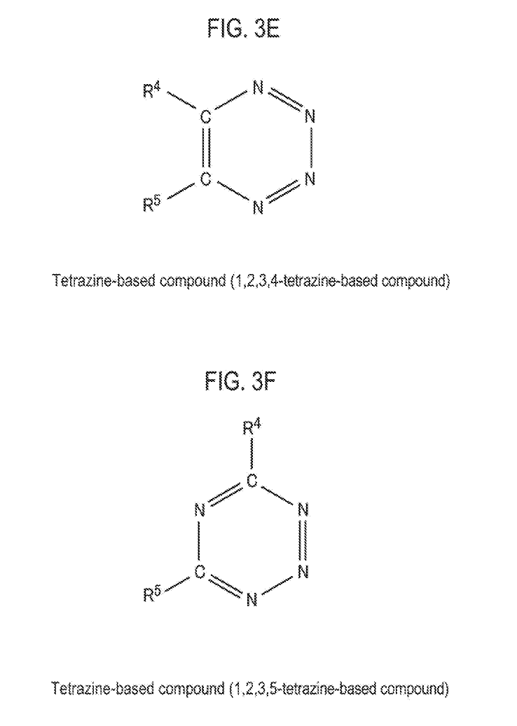

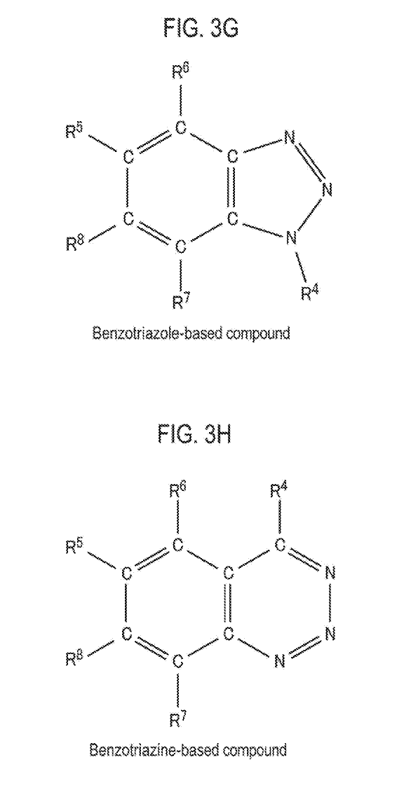

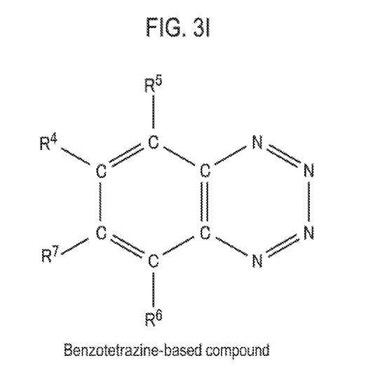

triazole-based compound (FIG. 3A),

oxatriazole-based compound (FIG. 3B),

tetrazole-based compound (FIG. 3C),

triazine-based compound (FIG. 3D),

tetrazine-based compound (FIG. 3E: 1,2,3,4-tetrazine-based compound, FIG. 3F: 1,2,3,5-tetrazine-based compound),

benzotriazole-based compound (FIG. 3G),

benzotriazine-based compound (FIG. 3H), and

benzotetrazine-based compound (FIG. 3I).

In the formulas shown in FIGS. 3A to 3I, each of R⁴ to R⁸ represents a straight chain or branched alkyl group which has one to eight carbon atoms and which may have a hydrogen atom or a substituent.

An example of the straight chain or branched alkyl group having one to eight carbon atoms may include:

methyl group,

ethyl group,

n-propyl group,

isopropyl group,

n-butyl group,

isobutyl group,

t-butyl group,

n-pentyl group,

isopentyl group,

t-pentyl group,

n-hexyl group,

isohexyl group,

t-hexyl group,

n-heptyl group,

isoheptyl group,

t-heptyl group,

n-octyl group,

isooctyl group, and

t-octyl group.

In practice, the alkyl group is preferably the methyl group, the ethyl group and the n-propyl group. More preferably, the alkyl group is the methyl group.

The substituent may be a straight chain or branched monoalkylamino group or dialkylamino group substituted with an alkyl group having one to four carbon atoms. More specifically, the substituent may be:

monomethylamino group,

dimethylamino group,

monoethylamino group,

diethylamino group,

monopropylamino group,

monoisopropylamino group, and

ethylmethylamino group.

In practice, the substituent is preferably the monomethylamino group and the dimethylamino group. More preferably, the substituent is the dimethylamino group.

In addition, the substituent may be a straight chain or branched alkoxy group having one eight carbon atoms. More specifically, the substituent may be:

methoxy group,

ethoxy group,

propoxy group,

butoxy group,

pentoxy group,

hexyloxy group,

heptyloxy group, and

octyloxy group.

In practice, the substituent is preferably the methoxy group, the ethoxy group and the propoxy group. More preferably, the substituent is the methoxy group.

In addition, for example, the nitrogen-containing heterocyclic compound gas expressed by FIG. 3A is a gas containing a 1,2,3-triazole-based compound. Examples of the 1,2,3-triazole-based compound may include:

1H-methyl-1,2,3-triazole,

1-methyl-1,2,3-triazole,

1,4-dimethyl-1,2,3-triazole,

1,4,5-trimethyl-1,2,3-triazole,

1-ethyl-1,2,3-triazole,

1,4-diethyl-1,2,3-triazole, and

1,4,5-triethyl-1,2,3-triazole.

In addition, the 1,2,3-triazole-based compound may be used alone or in a mixture of two or more kinds of compounds.

In addition, although examples of the oxatriazole-based compound (FIG. 3B), tetrazole-based compound (FIG. 3C), triazine-based compound (FIG. 3D), tetrazine-based compound (FIGS. 3E and 3F), benzotriazole-based compound (FIG. 3G), benzotriazine-based compound (FIG. 3H), and benzotetrazine-based compound (FIG. 3I) are not provided herein, it is to be understood that these compounds have many examples, as with the triazole-based compound.

### <Seed Conditions>

Examples of conditions in a seed process shown in Step S1 will be described below.

### <<Case Where Aminosilane-Based Gas is Used>>

One example of the aminosilane-based gas is BTBAS. One example of seed conditions in this case is as follows:

BTBAS flow rate: 100 sccm

Processing time: 1 min

Processing temperature: 550 degrees C.

Processing pressure: 13.33 Pa (0.1 Torr)

In the present disclosure, 1 Torr is defined as 133.3 Pa.

### <<Case Where High-Order Aminosilane-Based Gas is Used>>

One example of the high-order aminosilane-based gas is DIPADS (diisopropylaminodisilane). One example of seed conditions in this case is as follows:

DIPADS flow rate: 100 sccm

Processing time: 5 min

Processing temperature: 350 degrees C.

Processing pressure: 13.33 Pa (0.1 Torr).

### <<Case Where Nitrogen-Containing Heterocyclic Compound Gas is Used>>

One example of the nitrogen-containing heterocyclic compound gas is 1H-1,2,3-triazole. One example of seed conditions in this case is as follows:

Triazole flow rate: 300 sccm

Processing time: 10 min

Processing temperature: 350 degrees C.

Processing pressure: 1200 Pa (9 Torr).

When the seed processing is performed for the wafer 1 under one of the above-mentioned seed conditions, the seed layer 3 is formed on the surface of the silicon oxide film 2 to be processed, as shown in FIG. 2B.

Next, as shown in Step S2 of FIG. 1, a carbon film 4 is formed on the surface to be processed (the surface of the silicon oxide film 2) on which the seed layer 3 is formed, by supplying a hydrocarbon-based carbon source gas and a thermal decomposition temperature lowering gas for lowering the thermal decomposition temperature of the hydrocarbon-based carbon source gas onto the surface to be processed (the surface of the silicon oxide film 2) on which the seed layer 3 is formed. A film formation temperature at the time of forming the carbon film 4 is set to be lower than the thermal decomposition temperature of the hydrocarbon-based carbon source gas. For example, the film formation temperature is set to be equal to or higher than a temperature at which the hydrocarbon-based carbon source gas can be thermally decomposed by the thermal decomposition temperature lowering gas and equal to or lower than 650 degrees C., preferably 400 degrees C. The reason for setting the film formation temperature equal to or lower than 400 degrees C. is to suppress a heat history which affects a semiconductor integrated circuit device to be manufactured. In order to provide good step coverage of the carbon film 4, the formation of the carbon film 4 is preferably performed by a non-plasma thermal CVD method, wherein the film formation temperature is set to be lower than the thermal decomposition temperature available in the absence of plasma assist of the single hydrocarbon-based carbon source gas.

An example of the hydrocarbon-based carbon source gas may include a gas containing at least one of hydrocarbon compounds expressed by the following molecular formula:

CₙH₂ₙ₊₂ (C), or

CₘH₂ₘ (D), or

CₘH₂ₘ₋₂ (E).

In the formulas (C) to (E), n is a number of “1” or more and m is a number of “2” or more.

In addition, the hydrocarbon-based carbon source gas may include a benzene gas (C₆H₆).

An example of the hydrocarbon-based carbon source gas expressed by the formula (C) may include:

methane gas (CH₄),

ethane gas (C₂H₆),

propane gas (C₃H₈),

butane gas (C₄H₁₀: including other isomers), and

pentane gas (C₅H₁₂: including other isomers).

An example of the hydrocarbon-based carbon source gas expressed by the formula (D) may include:

ethylene gas (C₂H₄),

propylene gas (C₃H₆: including other isomers),

butylene gas (C₄H₈: including other isomers), and

pentene gas (C₅H₁₀: including other isomers).

An example of the hydrocarbon-based carbon source gas expressed by the formula (E) may include:

acetylene gas (C₂H₂),

propyne gas (C₃H₄: including other isomers),

butadiene gas (C₄H₆: including other isomers), and

isoprene gas (C₅H₈: including other isomers).

An example of the thermal decomposition temperature lowering gas may include a gas containing a halogen element such as fluorine (F), chlorine (Cl), bromine (Br) and iodine (I).

In addition, these halogen elements are preferably supplied as a single fluorine (F₂) gas, a single chlorine (Cl₂) gas, a single bromine (Br₂) gas and a single iodine (I₂) gas rather than compound gases. This is because, if the halogen elements are a form of a halogen element compound gas, heat is required to thermally decompose the compound gas. Thus, there is a possibility that the effect of lowering the thermal decomposition temperature of the hydrocarbon-based carbon source gas is reduced.

Further, among these halogen elements, fluorine has higher reactivity chlorine, bromine and iodine. Therefore, fluorine has a possibility of impairing the surface roughness and flatness of the carbon film to be formed. Rather than fluorine, therefore, chlorine, bromine and iodine are preferably selected as the halogen element.

In addition, for the purpose of safety at handling, chlorine is preferably selected rather than bromine and iodine.

### <<Conditions of Carbon Film Formation>>

Examples of conditions in a carbon film forming process shown in Step S2 will be described below.

One example of the hydrocarbon-based carbon source gas is a C₅H₈ gas. One example of the thermal decomposition temperature lowering gas is a Cl₂ gas. One example of carbon film formation conditions in this case is as follows:

C₅H₈ gas flow rate: 100 sccm

Cl₂ gas flow rate: 25 sccm

Processing time: 180 min

Film formation temperature: 350 degrees C.

Processing pressure: 200 Pa (1.5 Torr).

When the film forming process is performed for the wafer 1 under the above-mentioned carbon film formation conditions, the carbon film 4 is formed on the surface of the silicon oxide film 2 which is the surface to be processed on which the seed layer 3 is formed, as shown in FIG. 2C.

When the carbon film forming process shown in Step S2 is ended, the film formation of the carbon film 4 using the carbon film forming method according to the first embodiment is ended.

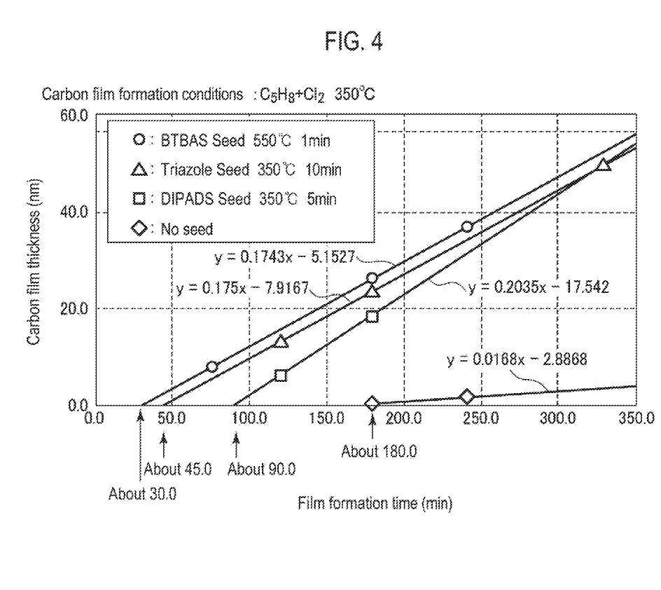

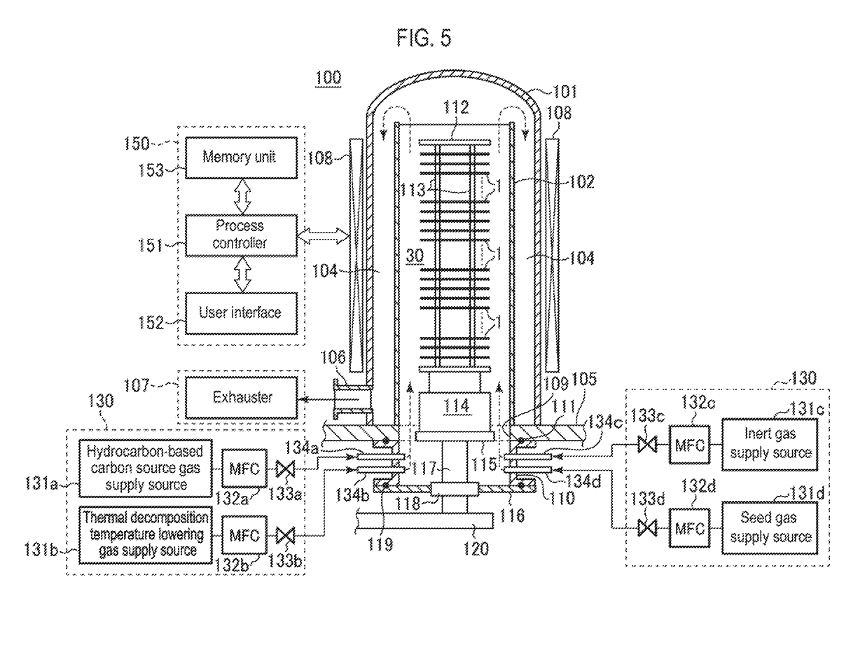

FIG. 4 is a view showing the relationship between film formation time and carbon film thickness. FIG. 4 shows four cases: (a) a case where BTBAS is used to perform the seed processing (O: BTBAS seed), (b) a case where 1H-1,2,3-triazole is used to perform the seed processing (Δ: Triazole seed), (c) a case where DIPADS is used to perform the seed processing (□: DIPADS seed), and (d) a case where no seed processing is performed (⋄: No seed). The seed conditions in the cases (a) to (c) are the same as those in shown in the above-described <<Case where Aminosilane-based Gas is Used>>, <<Case where High-Order Aminosilane-based Gas is Used>> and <<Case where Nitrogen-Containing Heterocyclic Compound Gas is Used>>. In addition, the carbon film formation conditions in the cases (a) to (d) are the same as shown in the above-described <<Conditions of Carbon Film Formation>>.

First, in the case (d) where no seed processing is performed, the incubation time of the carbon 4 was about 180 min.

In contrast, in the case (a) where BTBAS is used to perform the seed processing, the incubation time of the carbon film 4 was about 30 min, showing an improvement of about a reduction of 150 min.

In the case (b) where 1H-1,2,3-triazole is used to perform the seed processing, the incubation time of the carbon film 4 was about 45 min, showing improvement of about 135 min.

In the case (c) where DIPADS is used to perform the seed processing, the incubation time of the carbon film 4 was about 90 min, showing improvement of about 90 min.

In this manner, when the seed processing is performed for the surface to be processed of the wafer 1, for example, the surface of the silicon oxide film 2, before the carbon film 4 is formed, the incubation time of the carbon film 4 on the silicon oxide film 2 can be shortened.

Therefore, according to the first embodiment, even when the thermal decomposition temperature lowering gas is used in forming the carbon film and the film formation temperature is set to be lower than the thermal decomposition temperature of the hydrocarbon-based carbon source gas, for example, 800 degrees C. or less, it is possible to provide a carbon film forming method capable of shortening the incubation time. In addition, in the first embodiment, by forming the carbon film at a temperature lower than that in the conventional thermal CVD without using the plasma assist, it is possible to achieve a carbon film 4 having good step coverage. In addition, since the incubation time can be shortened, it is possible to obtain better surface roughness of the carbon film compared with a case of longer incubation time.

Regarding the incubation time, the seed gases, which are used for the seed processing, have a shorter incubation time in this order, the “aminosilane-based gas,” the “nitrogen-containing heterocyclic compound gas” and the “high-order aminosilane-based gas”. As a result, in order to obtain shorter incubation time, it is preferable to select the “aminosilane-based gas” or the “nitrogen-containing heterocyclic compound gas”.

In addition, from the viewpoint of processing temperature for the seed processing, the seed gases may be arranged from a lower processing temperature in the order of “nitrogen-containing heterocyclic compound gas”, the “high-order aminosilane-based gas” and the “aminosilane-based gas”. As a result, in order to lower the processing temperature for the seed processing, it is preferable to select the “nitrogen-containing heterocyclic compound gas” or the “high-order aminosilane-based gas”. In particular, when the “nitrogen-containing heterocyclic compound gas” or the “high-order aminosilane-based gas” is selected, the processing temperature for the seed processing and the film formation temperature for the subsequent carbon film formation can have the same level.

In this way, when the processing temperature for the seed processing has the same level as (for example, is equal to) the film formation temperature for the carbon film formation, the film forming apparatus may not perform adjustment (i.e., increase/decrease) of temperature in transitioning from the seed processing to the carbon film formation, which may result in reduced standby time during the film forming process and hence an improved throughput.

Furthermore, in view of both of the incubation time and the processing temperature for the seed processing, it is advantageous to select the “nitrogen-containing heterocyclic compound gas,” as the seed gas, rather than the “aminosilane-based gas” and the “high-order aminosilane-based gas”. The incubation time shortened by the “nitrogen-containing heterocyclic compound gas” was about 30 min with respect to about 45 min, although it was smaller than that shortened by the “aminosilane-based gas”. Therefore, in practice, the “nitrogen-containing heterocyclic compound gas” and the “aminosilane-based gas” can be regarded to have substantially the same capability.

### Second Embodiment

A second embodiment involves one example of a film forming apparatus capable of performing the carbon film forming method according to the first embodiment.

FIG. 5 is a schematic sectional view showing one example of a vertical batch type film forming apparatus according to a second embodiment of the present disclosure.

As shown in FIG. 5, a vertical batch type film forming apparatus (hereinafter referred simply to as a film forming apparatus) 100 includes a cylindrical outer wall 101 with a ceiling, and a cylindrical inner wall 102 provided in the inner side of the outer wall 101. The outer wall 101 and the inner wall 102 are made of, e.g., quartz. The inside of the inner wall 102 corresponds to a processing chamber 30 in which workpieces (in this embodiment, a plurality of wafers 1) are accommodated, and in which a film forming process is performed together for the plurality of accommodated wafers 1. In the interior of the processing chamber 30, the carbon film forming method described in the first embodiment is performed together for the plurality of wafers 1.

The outer wall 101 and the inner wall 102 are separated from each other along the horizontal direction, with an annular space 104 defined therebetween, and their respective bottoms are bonded to abase member 105. The top of the inner wall 102 is separated from the ceiling of the outer wall 101 and the upper side of the processing chamber 30 communicates to the annular space 104. The annular space 104 communicating to the upper side of the processing chamber 30 forms exhaust path. A gas supplied and spread into the processing chamber 30 flows upward through the processing chamber 30 and is sucked into the annular space 104. An exhaust pipe 106 is connected to the lower end portion of the annular space 104. The exhaust pipe 106 is also connected to an exhauster 107. The exhauster 107 is configured to include a vacuum pump (not shown) or the like to exhaust a gas used for processing from the interior of the processing chamber 30 and adjust the internal pressure of the processing chamber 30 to a pressure appropriate for processing.

In the outside of the outer wall 101, a heater 108 is disposed so as to surround the processing chamber 30. The heater 108 heats the workpieces (in this embodiment, the plurality of wafers 1) by adjusting the internal temperature of the processing chamber 30 to a temperature appropriate for processing.

The lower side of the processing chamber 30 communicates to an opening 109 formed in the base member 105. A cylindrical manifold 110 made of, e.g., stainless steel is connected to the opening 109 via a seal member 111 such as an O-ring. The lower end portion of the manifold 110 is formed with an opening through which a boat 112 is inserted in the processing chamber 30. The boat 112 is made of, e.g., quartz and has a plurality of posts 113. The posts 113 are each formed with grooves (not shown) by which a plurality of substrates to be processed is supported at once. Thus, as the substrates to be processed, a plurality of (e.g., 50 to 150) wafers 1 can be mounted in multiple stages on the boat 112. By inserting the boat 112 on which the plurality of wafers 1 is mounted into the processing chamber 30, the plurality of wafers 1 can be accommodated in the processing chamber 30.

The boat 112 is mounted on a table 115 through a heat reserving tube 114 made of quartz. The table 115 is supported on a rotary shaft 117 penetrating through a cover member 116 made of, e.g., stainless steel. The cover member 116 opens/closes the opening of the lower end portion of the manifold 110. The penetration portion of the cover member 116 is provided with, e.g., a magnetic fluid seal 118 which rotatably supports the rotary shaft 117 while sealing the rotary shaft 117 in an airtight manner. In addition, a seal member 119 such as an O-ring is interposed between the periphery of the cover member 116 and the lower end portion of the manifold 110 so as to maintain the sealability of the interior of the processing chamber 30. The rotary shaft 117 is attached to a leading end of an arm 120 supported by an elevation mechanism (not shown) such as a boat elevator. With this configuration, the wafer boat 112, the cover member 116, and so on are integrally ascended/descended in the vertical direction so as to be loaded in/unloaded from the processing chamber 30.

The film forming apparatus 100 includes a processing gas supply mechanism 130 for supplying gases used for processing into the processing chamber 30.

In this embodiment, the processing gas supply mechanism 130 includes a hydrocarbon-based carbon source gas supply source 131a, a thermal decomposition temperature lowering gas supply source 131b, an inert gas supply source 131c and a seed gas supply source 131d. In this embodiment, a C₅H₈ gas is used as the hydrocarbon-based carbon source gas, a Cl₂ gas is used as the thermal decomposition temperature lowering gas, an N₂ gas is used as the inert gas, and a BTBAS gas or a DIPADS gas or a 1H-1,2,3-triazole gas is used as the seed gas.

The hydrocarbon-based carbon source gas supply source 131a is connected to a gas supply port 134a via a mass flow controller (MFC) 132a and an opening/closing valve 133a. Similarly, the thermal decomposition temperature lowering gas supply source 131b is connected to a gas supply port 134b via a mass flow controller (MFC) 132b and an opening/closing valve 133b. The inert gas supply source 131c is connected to a gas supply port 134c via a mass flow controller (MFC) 132c and an opening/closing valve 133c. The seed gas supply source 131d is connected to a gas supply port 134d via a mass flow controller (MFC) 132d and an opening/closing valve 133d. Each of the gas supply ports 134a to 134d is placed to penetrate through the side wall of the manifold 110 along the horizontal direction and spreads the supplied gases into the processing chamber 30 above the manifold 110.

A control unit 150 is connected to the film forming apparatus 100. The control unit 150 includes a process controller 151 such as a microprocessor (computer) which controls various components of the film forming apparatus 100. A user interface 152 and a memory unit 153 are connected to the process controller 151.

The user interface 152 includes an input unit including a touch panel display, a keyboard and the like for allowing an operator to input a command to control the film forming apparatus 100, and a display unit including a display for visually displaying an operation state of the film forming apparatus 100.

The memory unit 153 stores a control program for executing various processes in the film forming apparatus 100 under the control of the process controller 151, and a program (i.e., a so-called process recipe) for causing the respective components of the film forming apparatus 100 to execute the respective processes according to the process conditions. The process recipe is stored in a memory medium of the memory unit 153. The memory medium may include a hard disk, a semiconductor memory, or a portable memory such as a CD-ROM, a DVD, a flash memory or the like. The process recipe may be suitably transmitted from other device through a dedicated line.

If necessary, the process recipe is read from the memory unit 153 in response to a command received from the user interface 152, and the process controller 151 executes a process according to the read process recipe. Accordingly, the film forming apparatus 100 performs a desired process under the control of the process controller 151. In this embodiment, the film forming apparatus 100 performs the processes according to the carbon film forming method described in the first embodiment under the control of the controller 151.

The carbon film forming method according to the first embodiment can be performed, for example by the vertical batch type film forming apparatus 100 as shown in FIG. 5.

Although the present disclosure has been described according to the first and second embodiments, the present disclosure is not limited thereto. Other different embodiments may be made without departing from the spirit of the disclosure.

For example, although the detailed process conditions have been illustrated in the above embodiments, the present disclosure is not limited thereto.

In addition, although it has been illustrated in the above embodiments that the vertical batch type film forming apparatus is used to form the carbon film, it is to be understood that other non-vertical batch type film forming apparatus as well as a single-wafer film forming apparatus may be employed to form the carbon film.

According to the present disclosure in some embodiments, it is possible to provide a method for forming a carbon film, which is capable of shortening incubation time even when a thermal decomposition temperature lowering gas is used in forming a carbon film and a film formation temperature is set to be lower than a thermal decomposition temperature of a hydrocarbon-based carbon source gas, and a film forming apparatus capable of performing the same method.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method for forming a carbon film on a process surface to be processed of a workpiece, the method comprising:
forming a seed layer on the process surface of the workpiece by supplying an aminosilane-based gas, an aminosilane-based gas having high-order equal to or higher than that of aminodisilane, or a nitrogen-containing heterocyclic compound gas onto the process surface; and
forming the carbon film on the process surface on which the seed layer is formed by supplying a hydrocarbon-based carbon source gas and a thermal decomposition temperature lowering gas for lowering a thermal decomposition temperature of the hydrocarbon-based carbon source gas onto the process surface on which the seed layer is obtained, and by setting a film formation temperature to be lower than the thermal decomposition temperature of the hydrocarbon-based carbon source gas.

2. The method of claim 1, wherein the film formation temperature is set to be equal to or higher than a temperature at which the hydrocarbon-based carbon source gas can be thermally decomposed by the thermal decomposition temperature lowering gas, and to be equal to or less than 650 degrees C.

3. The method of claim 1, wherein a processing temperature in the forming a seed layer is set to be equal to or higher than the thermal decomposition temperature of each of the aminosilane-based gas, the aminosilane-based gas having high-order equal to or higher than that of aminodisilane, and the nitrogen-containing heterocyclic compound gas.

4. The method of claim 1, wherein, when the aminosilane-based gas is selected in the forming a seed layer, a processing temperature in the forming a seed layer is set to be equal to or higher than the film forming temperature, and
wherein, when the aminosilane-based gas having high-order equal to or higher than that of aminodisilane or the nitrogen-containing heterocyclic compound gas is selected in the forming a seed layer, a processing temperature in the forming a seed layer is set to be equal to the film forming temperature.

5. The method of claim 1, wherein a silicon oxide film is exposed on the process surface.

6. The method of claim 1, wherein the film formation temperature is set to be lower than the thermal decomposition temperature of the hydrocarbon-based carbon source gas available in the absence of plasma assist of a single hydrocarbon-based carbon source gas, and
wherein the carbon film is formed by a non-plasma thermal CVD method.

7. The method of claim 1, wherein the aminosilane-based gas is a gas containing at least one selected from a group consisting of:
BAS (butylaminosilane),
BTBAS (bistertiarybutylaminosilane),
DMAS (dimethylaminosilane),
BDMAS (bisdimethylaminosilane),
TDMAS (trisdimethylaminosilane),
DEAS (diethylaminosilane),
BDEAS (bisdiethylaminosilane),
DPAS (dipropylaminosilane), and
DIPAS (Diisopropylaminosilane).

8. The method of claim 1, wherein the aminosilane-based gas having high-order equal to or higher than that of aminodisilane is a gas containing at least one of amino compounds expressed by a molecular formula:
((R1R2)N)ₙSi_{X}H_{2X+2-n-m}(R3)ₘ (A), or
((R1R2)N)ₙSi_{X}H_{2X-n-m}(R3)ₘ (B),
wherein, in the formulas (A) and (B), n represents the number of amino groups equal to or higher than “1”, m represents the number of alkyl groups equal to “0” or equal to or higher than “1”, R1 and R2 are independently selected from a group consisting of CH₃, C₂H₅, and C₃H₇, R3 is selected from a group consisting of CH₃, C₂H₅, C₃H₇ and Cl, and X is a number of “2” or more.

9. The method of claim 1, wherein the nitrogen-containing heterocyclic compound gas is a gas containing at least one selected from a group consisting of:
triazole-based compound,
oxatriazole-based compound,
tetrazole-based compound,
triazine-based compound,
tetrazine-based compound,
benzotriazole-based compound,
benzotriazine-based compound, and
benzotetrazine-based compound.

10. The method of claim 1, wherein the hydrocarbon-based carbon source gas is a gas containing hydrocarbon expressed by at least one of molecular formulas:
CₙH₂ₙ₊₂ (C),
CₘH₂ₘ (D), and
CₘH₂ₘ₋₂ (E),
in the formulas (C) to (E), n is a number of “1” or more and m is a number of “2” or more.

11. The method of claim 1, wherein the thermal decomposition temperature lowering gas is a gas containing at least one selected from a group consisting of:
fluorine,
chlorine,
bromine, and
iodine.

12. A film forming apparatus for forming a carbon film on a process surface to be processed of a workpiece, comprising:
a processing chamber in which the workpiece having the process surface on which the carbon film is to be formed is accommodated;
a processing gas supply mechanism configured to supply a gas to be used for processing into the processing chamber;
a heater configured to heat the workpiece accommodated in the processing chamber; and
a controller configured to control the processing gas supply mechanism and the heater so as to perform the carbon film forming method of claim 1.
